(19) United States
(12) Patent Application Publication
(10) Pub. No.: US 2024/0194770 A1
(43) Pub. Date: Jun. 13, 2024

(54) HETEROJUNCTION BIPOLAR TRANSISTOR, SEMICONDUCTOR DEVICE, AND COMMUNICATION MODULE

(71) Applicant: Murata Manufacturing Co., Ltd., Kyoto-fu (JP)

(72) Inventors: Takayuki TSUTSUI, Nagaokakyo-shi (JP); Masao KONDO, Nagaokakyo-shi (JP); Shaojun MA, Nagaokakyo-shi (JP)

(73) Assignee: Murata Manufacturing Co., Ltd., Kyoto-fu (JP)

(21) Appl. No.: 18/583,693

(22) Filed: Feb. 21, 2024

Related U.S. Application Data
(63) Continuation of application No. PCT/JP2022/033762, filed on Sep. 8, 2022.

(30) Foreign Application Priority Data
Oct. 19, 2021 (JP) 2021-171063

(51) Int. Cl. H01L 29/73; H01L 27/06; H01L 29/205; H01L 29/737; H01L 29/778; H03F 3/21

(52) U.S. Cl. CPC H01L 29/7304; H01L 27/0623; H01L 29/205; H01L 29/7371; H01L 29/7786; H03F 3/211; H03F 2200/451

(57) ABSTRACT

A heterojunction bipolar transistor includes a collector layer, a base layer, an emitter layer, and a ballast resistance layer. The collector layer is made of an n-type compound semiconductor material. The base layer is disposed on the collector layer and is made of a p-type compound semiconductor material. The emitter layer is disposed on the base layer and is made of an n-type compound semiconductor material having a band gap larger than a band gap of the base layer. The ballast resistance layer is disposed on the emitter layer and is made of an intrinsic or p-type compound semiconductor material.

### CROSS-REFERENCE TO RELATED APPLICATIONS

This application claims benefit of priority to International Patent Application No. PCT/JP2022/033762 filed Sep. 8, 2022, and to Japanese Patent Application No. 2021-171063, filed Oct. 19, 2021, the entire contents of each are incorporated herein by reference.

### BACKGROUND

### Technical Field

The present disclosure relates to a heterojunction bipolar transistor, a semiconductor device, and a communication module.

### Background Art

Carrier aggregation (CA) has been adopted into mobile terminals with a view to providing high transmission capacity. Such a mobile terminal is expected to be adaptable for Sub-6 GHz applications in the fifth-generation mobile communication system. To this end, a radio-frequency power amplifier that is one of the principal components of the mobile terminal is configured to cover multiple frequency bands. The use of more frequency bands requires a radio-frequency front-end circuit with a highly complex configuration.

The increased complexity of the configuration of the radio-frequency front-end circuit leads to an increase in the load loss of the radio-frequency power amplifier. Such a radio-frequency power amplifier that covers more frequency bands is thus expected to be capable of providing higher output power. Examples of amplifying elements for use in radio-frequency power amplifiers include heterojunction bipolar transistors (HBTs). With a trend toward radio-frequency power amplifiers with higher output power, emphasis is being placed on making HBTs less susceptible to breakdown. It is therefore desired not only to provide circuitry protection for HBTs but also to use HBTs with higher breakdown voltage.

A known technique for providing such an HBT with higher breakdown voltage involves placing a ballast resistance layer between an emitter layer and an emitter electrode as described, for example, in Japanese Unexamined Patent Application Publication No. 10-335345. The HBT disclosed in Japanese Unexamined Patent Application Publication No. 10-335345 includes an n⁻-GaAs ballast resistance layer disposed between an n-AlGaAs emitter layer and an emitter electrode.

### SUMMARY

The approach described in Japanese Unexamined Patent Application Publication No. 10-335345 necessitates increasing the thickness of the ballast resistance layer so that the HBT can achieve a desired breakdown voltage. Performing etching to form such a thick ballast resistance layer may lead to element-to-element size variation due to the accompanying impairment of processing accuracy. Consequently, HBTs will have poor yield rates. One of the purposes of the present disclosure is to provide an HBT including a thinner ballast resistance layer. Another purpose of the present disclosure is to provide a semiconductor device including the HBT. Still another purpose of the present disclosure is to provide a communication module in which the HBT is incorporated.

An aspect of the present disclosure provides a heterojunction bipolar transistor including a collector layer, a base layer, an emitter layer, and a ballast resistance layer. The collector layer is made of an n-type compound semiconductor material. The base layer is disposed on the collector layer and is made of a p-type compound semiconductor material. The emitter layer is disposed on the base layer and is made of an n-type compound semiconductor material having a band gap larger than a band gap of than the base layer. The ballast resistance layer is disposed on the emitter layer and is made of an intrinsic or p-type compound semiconductor material.

Another aspect of the present disclosure provides a semiconductor device including a substrate, the heterojunction bipolar transistor disposed on the substrate, and a high-electron-mobility transistor disposed on the substrate.

Still another aspect of the present disclosure provides a communication module including the heterojunction bipolar transistor, an antenna terminal, and a frequency selection element. The antenna terminal is connected to an antenna. The frequency selection element is connected between the heterojunction bipolar transistor and the antenna terminal.

The ballast resistance layer made of an intrinsic or p-type compound semiconductor can be reduced in thickness while maintaining a desired resistance value. The present disclosure can thus provide an HBT with higher breakdown voltage and reduce variation in processing accuracy.

### BRIEF DESCRIPTION OF THE DRAWINGS

FIG. 1 is a plan view of an HBT in Example 1;

FIG. 2 is a sectional view of the HBT taken along dash-dot line 2-2 in FIG. 1;

FIG. 3 is a graph illustrating the result of simulations that were conducted on the HBT in Example 1 and an HBT in Comparative Example to determine the relationship between emitter current and emitter voltage;

FIG. 4 is a sectional view of an HBT in Example 2;

FIG. 5 is a plan view of an HBT in Example 3;

FIG. 6 is a sectional view of the HBT taken along dash-dot line 6-6 in FIG. 5;

FIG. 7 is a plan view of an HBT in a variation of Example 3;

FIG. 8 is a sectional view of the HBT taken along dash-dot line 8-8 in FIG. 7;

FIG. 9 is a sectional view of a BiHEMT in Example 4;

FIG. 10 is a block diagram of a communication module in Example 5;

FIG. 11 is a plan view of a module substrate of the communication module in Example 5, illustrating an example layout of various circuit elements mounted on the module substrate;

FIG. 12 is an equivalent circuit diagram of part of a power-stage amplifier;

FIG. 13 is a plan view of part of the power-stage amplifier; and

FIG. 14 is a block diagram of a communication module in a variation of Example 5.

### DETAILED DESCRIPTION

### Example 1

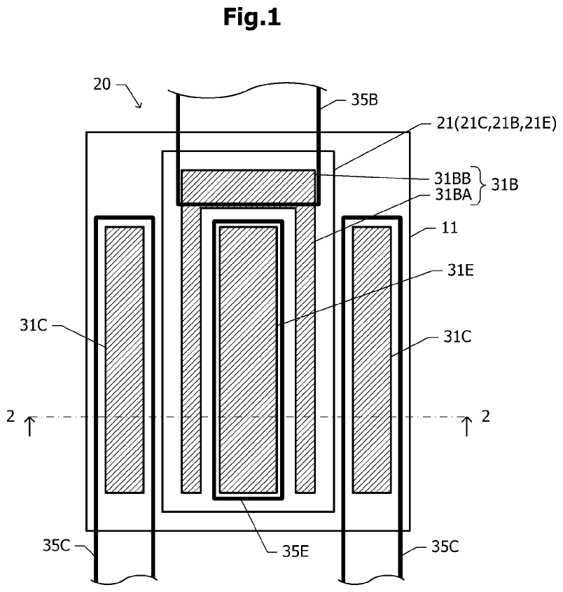

The following describes a heterojunction bipolar transistor (HBT) in Example 1 with reference to FIGS. 1, 2, and 3. FIG. 1 is a plan view of an HBT 20 in Example 1. When viewed in plan, a collector mesa 21 is located within a sub-collector layer 11, which is made of an n-type compound semiconductor material. The collector mesa 21 includes a collector layer 21C, a base layer 21B, and an emitter layer 21E.

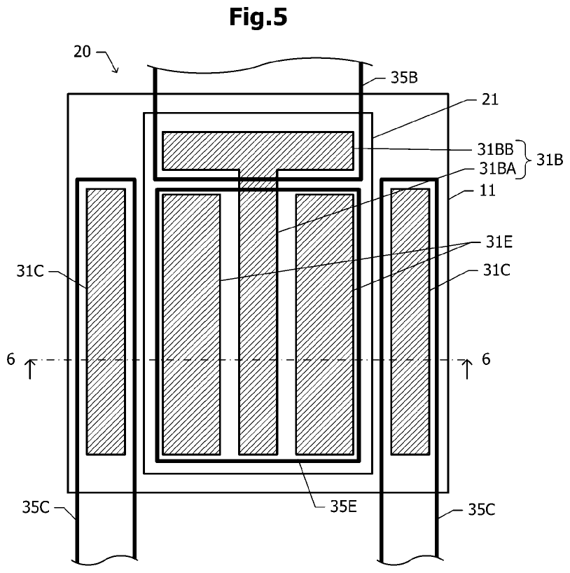

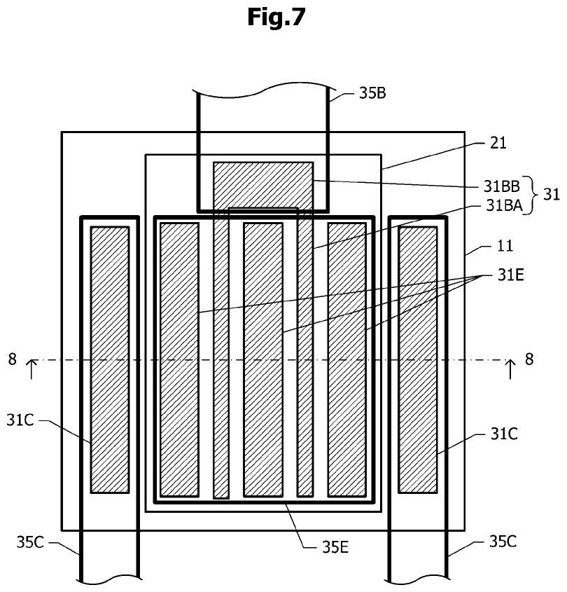

When viewed in plan, an emitter electrode 31E and a base electrode 31B are located within the collector mesa 21. The emitter electrode 31E is longer in one direction than in the other directions when viewed in plan. The base electrode 31B is U-shaped when viewed in plan. The base electrode 31B includes a pair of finger portions 31BA and a contact portion 31BB. The finger portions 31BA are disposed on opposite sides with the emitter electrode 31E located therebetween in the width direction thereof. The contact portion 31BB forms a connection between an end of one of the finger portions 31BA and an end of the other finger portion 31BA. When viewed in plan, two collector electrodes 31C are disposed on opposite sides with the collector mesa 21 located therebetween in the width direction of the emitter electrode 31E. Referring to FIG. 1, the emitter electrode 31E, the base electrode 31B, and the collector electrodes 31C are hatched. Likewise, these electrodes in FIGS. 5 and 7 are hatched.

The emitter electrode 31E is located substantially within an emitter line 35E in a first layer when viewed in plan. The emitter line 35E is electrically connected to the emitter electrode 31E. The contact portion 31BB of the base electrode 31B is located within a base line 35B in the first layer when viewed in plan. The base line 35B is electrically connected to the contact portion 31BB. The base line 35B overlying the contact portion 31BB is extended beyond an edge of the collector mesa 21 and an edge of the sub-collector layer 11. Collector lines 35C in the first layer extend over the respective collector electrodes 31C. The collector lines 35C are electrically connected to the collector electrodes 31C. The collector lines 35C overlying the respective collector electrodes 31C are extended beyond another edge of the collector mesa 21 and another edge of the sub-collector layer 11. The direction in which the base lines 35B are extended is opposite to the direction in which the collector lines 35C are extended.

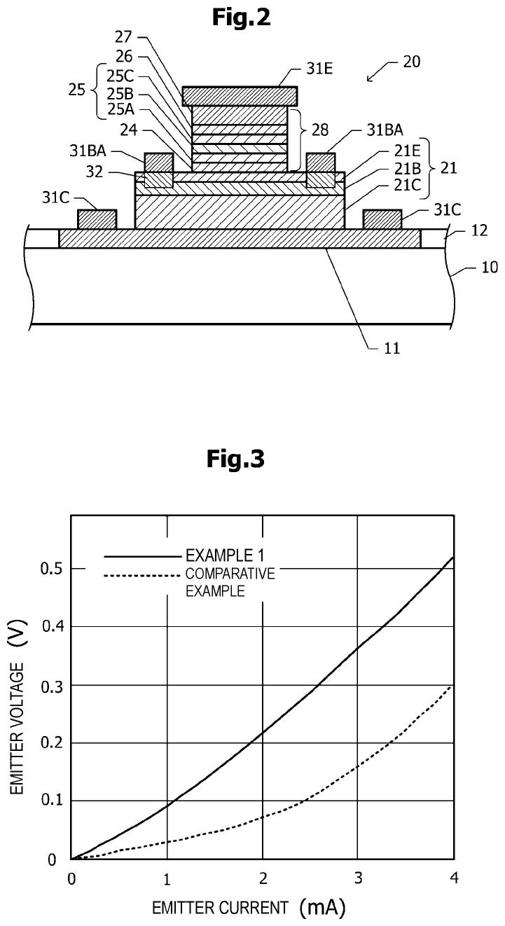

FIG. 2 is a sectional view of the HBT taken along dash-dot line 2-2 in FIG. 1. The sub-collector layer 11 made of an n-type compound semiconductor material is disposed on part of an upper surface of a substrate 10, which is made of a semi-insulating compound semiconductor material. The other part of the upper surface of the substrate 10 is overlaid with an insulating material, which is hereinafter referred to as an element isolation region 12.

The collector mesa 21 extends over part of the sub-collector layer 11. The collector mesa 21 includes the collector layer 21C on the substrate 10, the base layer 21B on the collector layer 21C, and the emitter layer 21E on the base layer 21B. The collector layer 21C is made of an n-type compound semiconductor material. The base layer 21B is made of a p-type compound semiconductor material. The emitter layer 21E is made of an n-type compound semiconductor material.

Part of the emitter layer 21E is overlaid with an emitter mesa 28. The emitter mesa 28 includes a high-concentration layer 24 on the emitter layer 21E, a ballast resistance layer 25 on the high-concentration layer 24, a high-concentration layer 26 on the ballast resistance layer 25, and a contact layer 27 on the high-concentration layer 26. The ballast resistance layer 25 includes a p-type layer 25B and n-type layers 25A and 25C. The p-type layer 25B is made of a p-type compound semiconductor material, and the two n-type layers respectively denoted by 25A and 25C are each made of an n-type compound semiconductor material. These layers are stacked on top of one another in the up-and-down direction, with the p-type layer 25B located between the n-type layers 25A and 25C. The high-concentration layers 24 and 26 and the contact layer 27 are each made of an n-type compound semiconductor material.

The two collector electrodes 31C are disposed on the upper surface of the sub-collector layer 11 with the collector mesa 21 located between the collector electrodes 31C. The collector electrodes 31C are electrically connected to the collector layer 21C via the sub-collector layer 11. The finger portions 31BA of the base electrode 31B (see FIG. 1) are disposed on an upper surface of the emitter layer 21E with the emitter mesa 28 located between the finger portions 31BA. The base electrode 31B is electrically connected to the base layer 21B via an alloy region 32, which extends through the emitter layer 21E and part of the base layer 21B. The emitter electrode 31E is disposed on the contact layer 27. The emitter electrode 31E is electrically connected to the emitter layer 21E via the contact layer 27, the high-concentration layer 26, the ballast resistance layer 25, and the high-concentration layer 24.

The HBT 20 illustrated in FIG. 2 is overlaid with an interlayer insulating film (not illustrated). The collector lines 35C, the base line 35B, and the emitter line 35E (see FIG. 1) in the first layer are disposed on the interlayer insulating film. The collector lines 35C, the base line 35B, and the emitter line 35E in the first layer extend through openings in the interlayer insulating film. Accordingly, the collector lines 35C are connected to the respective collector electrodes 31C. Likewise, the base line 35B and the emitter line 35E are connected to the base electrode 31B and the emitter electrode 31E, respectively.

Example compositions of the compound semiconductor materials of the layers constituting the HBT 20 are as follows. The substrate 10 is a semi-insulating GaAs substrate. The sub-collector layer 11 and the collector layer 21C are n-type GaAs layers. The donor concentration in the sub-collector layer 11 is higher than the donor concentration in the collector layer 21C. The base layer 21B is a p-type GaAs layer. In some embodiments, the base layer 21B is, for example, a p-type InGaAs layer. The emitter layer 21E is an n-type InGaP layer whose band gap is larger than the band gap of the base layer 21B. The high-concentration layers 24 and 26 are n-type GaAs layers.

The n-type layers 25A and 25C included in the ballast resistance layer 25 are n-type GaAs layers. The p-type layer 25B included in the ballast resistance layer 25 is a p-type GaAs layer. The n-type layers 25A and 25C have the same donor concentration. The donor concentration in the n-type layers 25A and 25C is lower than the donor concentration in each of the high-concentration layer 24, the high-concentration layer 26, the collector layer 21C, and the emitter layer 21E. The acceptor concentration in the p-type layer 25B is substantially equal to the donor concentration in the n-type layers 25A and 25C. The contact layer 27 is an n-type InGaAs layer.

The following describes advantageous effects of Example 1 with reference FIG. 3. FIG. 3 is a graph illustrating the result of simulations that were conducted on the HBT in Example 1 and an HBT in Comparative Example to determine the relationship between emitter current and emitter voltage. The horizontal axis represents emitter current in units of mA, and the vertical axis represents emitter voltage in units of V. The solid line in the graph represents the result of the simulation conducted on the HBT in Example 1, and the broken line in the graph represents the result of the simulation conducted on the HBT in Comparative Example. The term “emitter voltage” herein refers to a voltage between the upper surface of the emitter layer 21E and a lower surface of the contact layer 27.

The HBT in Comparative Example was obtained by replacing the ballast resistance layer 25 of the HBT 20 (see FIG. 2) in Example 1 with a low-concentration n-type GaAs layer (with a donor concentration of 1×10¹⁶ cm⁻³). The ballast resistance layer 25 of the HBT 20 in Example 1 was thinner than the low-concentration n-type GaAs layer of the HBT in Comparative Example. The donor concentration in each of the n-type layers 25A and 25C and the acceptor concentration in the p-type layer 25B were each set to 1×10¹⁶ cm⁻³.

As can be seen in the graph, the emitter voltage under the same condition of emitter current was higher in the HBT 20 in Example 1 than in the HBT in Comparative Example. This means that the ballast resistance of the HBT 20 in Example 1 is higher than the ballast resistance of the HBT in Comparative Example. Conversely, the ballast resistance layer 25 of the HBT 20 in Example 1 can be made thinner than the ballast resistance layer of the HBT in Comparative Example while it is ensured that the ballast resistance of the HBT 20 is set to a desired value. The reduction in the thickness of the ballast resistance layer 25 (see FIG. 2) translates into increases in processing accuracy for the emitter mesa 28 and the collector mesa 21. This enables reductions in product-to-product size variation. The greater processing accuracy can also lead to enhanced production yield and a reduction in production cost.

As mentioned above, the structure of the ballast resistance layer 25 in Example 1 enables an increase in the ballast resistance. The reason for this is as follows. The positive charge in the p-type layer 25B included in the ballast resistance layer 25 in Example 1 causes an upward shifting of the lower edge of the conduction band of the p-type layer 25B such that an arching curve is formed. The curve is a potential barrier for electrons. The potential barrier opposing applied voltage impedes current flow. The upward shifting of the potential in the p-type layer 25B yields a significant increase in the resistance of the ballast resistance layer 25. This is particularly true for high-current operation, in which case the resistance is increased to a greater extent than would be possible with the low-concentration n-type ballast resistance layer in Comparative Example. The ballast resistance layer 25 is thus more effective at eliminating or reducing the occurrence of thermal runaway.

The following describes functions of the layers constituting the emitter mesa 28 of the HBT 20 in Example 1. The high-concentration layer 24 between the emitter layer 21E and the ballast resistance layer 25 is intended to reduce the contact resistance between the emitter layer 21E and the ballast resistance layer 25. The high-concentration layer 26 between the ballast resistance layer 25 and the contact layer 27 is intended to reduce the contact resistance between the ballast resistance layer 25 and the contact layer 27.

The desired thickness of the ballast resistance layer 25 and the dopant concentration in the ballast resistance layer 25 are as follows. If the p-type layer 25B that is a low-concentration layer included in the ballast resistance layer 25 is in direct contact with the high-concentration layers 24 and 26, depletion layers formed at the respective p-n junction interfaces would extend into the p-type layer 25B. That is, there would be substantially no p-type layer between the high-concentration layer 24 on the lower side and the high-concentration layer 26 on the upper side when the depletion layers extending from the respective high-concentration layers are in contact with each other. As a workaround, low-concentration layers are disposed to eliminate or reduce the possibility that the depletion layers will extend into the p-type layer 25B. The low-concentration layers are the n-type layer 25A disposed between the high-concentration layer 24 and the p-type layer 25B and the n-type layer 25C disposed between the high-concentration layer 26 and the p-type layer 25B. It is preferred that the donor concentration in each of the n-type layers 25A and 25C and the acceptor concentration in the p-type layer 25B be substantially equal to each other so that the depletion layers will not extend into the p-type layer 25B.

If the p-type layer 25B has a low concentration of acceptor ions and is excessively reduced in thickness, the deletion layers extending from the p-n junction interfaces on the upper and lower sides would come into contact with each other in the p-type layer 25B during the application of voltage. This would lead to the substantial disappearance of the potential barrier. This phenomenon is called punch-through. If the punch-through occurs, the ballast resistance layer 25 would become unable to serve as a resistance element. It is therefore preferred that the acceptor concentration in the p-type layer 25B and the thickness of the p-type layer 25B be adjusted to the extent that the deletion layers extending from the p-n junction interfaces on the upper and lower sides are kept from coming into contact with each other in the p-type layer 25B during the application of operating voltage.

The electrons in the p-type layer 25B are minority carriers, in which case the current in the p-type layer 25B is dominated by a diffusion current of electrons. If the p-type layer 25B is excessively increased in thickness, the responsiveness of the emitter current would decline, leading to a reduction in cutoff frequency. Thus, the thickness of the p-type layer 25B is preferably less than or equal to the thickness of the base layer 21B. This eliminates or reduces the possibility that the cutoff frequency will decline.

If the donor concentration in each of the n-type layers 25A and 25C and the acceptor concentration in the p-type layer 25B are excessively increased, the voltage applied to the emitter would be localized to the p-n junction interfaces such that the ballast resistance layer 25 would behave as a diode under forward bias and a diode under reverse bias. The donor concentration in each of the n-type layers 25A and 25C and the acceptor concentration in the p-type layer 25B are each preferably less than or equal to 1×10¹⁶ cm⁻³ so that ballast resistance layer 25 can serve as a resistance element.

The desired material of the ballast resistance layer 25 is as follows. The ballast resistance layer 25 is preferably a compound semiconductor having a lattice matching to the collector layer 21C. It is particularly preferred that the ballast resistance layer 25 and the collector layer 21C include the same compound semiconductor. This means that the constituent elements of the compound semiconductor used as a material of the ballast resistance layer 25 and the constituent elements of the compound semiconductor used as a material of the collector layer 21C be preferably the same.

### Example 2

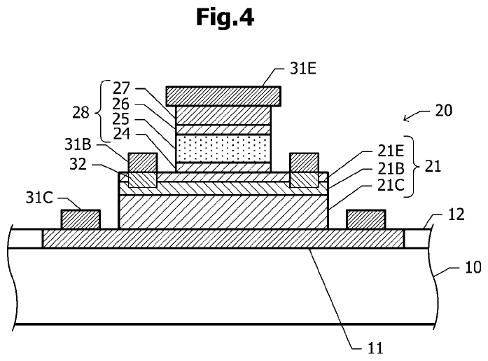

The following describes an HBT in Example 2 with reference to FIG. 4. The features of the HBT that are common to Example 2 and Example 1 described above with reference to FIGS. 1 to 3 will not be further elaborated on here.

FIG. 4 is a sectional view of the HBT 20 in Example 2. The ballast resistance layer 25 in Example 1 (see FIG. 2) includes three layers or, more specifically, the n-type layer 25A, the p-type layer 25B, and the n-type layer 25C, whereas the ballast resistance layer 25 in Example 2 is made of an intrinsic compound semiconductor material. For example, the ballast resistance layer 25 is an undoped GaAs layer.

The following describes advantageous effects of Example 2. The resistance value of the ballast resistance layer 25 made of an intrinsic compound semiconductor material is greater than if the ballast resistance layer 25 is made of a low-concentration n-type compound semiconductor material. As in Example 1, the ballast resistance layer 25 can be made thinner while it is ensured that the ballast resistance of the HBT is set to a desired value. This increases the processing accuracy for the emitter mesa 28 and the collector mesa 21.

The following describes a variation of Example 2. Example 2 involves replacing the n-type layer 25A, the p-type layer 25B, and the n-type layer 25C in Example 1 (see FIG. 2) with intrinsic compound semiconductor layers. Alternatively, only one of the three layers or, more specifically, the p-type layer 25B, and the n-type layer 25C in Example 1 (see FIG. 2) may be replaced with intrinsic compound semiconductor layers. In this case, the ballast resistance layer 25 has a three-layer structure in which an intrinsic compound semiconductor layer is sandwiched between an n-type layer on the upper side and an n-type layer on the lower side.

### Example 3

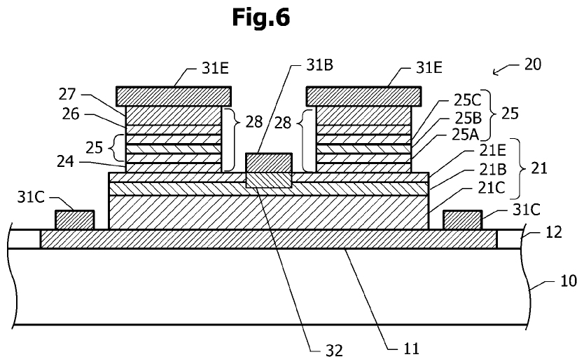

The following describes an HBT in Example 3 with reference to FIGS. 5 and 6. The features of the HBT that are common to Example 3 and Example 1 described above with reference to FIGS. 1 to 3 will not be further elaborated on here.

FIG. 5 is a plan view of the HBT 20 in Example 3, and FIG. 6 is a sectional view of the HBT 20 taken along dash-dot line 6-6 in FIG. 5. The HBT 20 (see FIG. 1) in Example 1 includes one emitter electrode 31E and one emitter mesa 28, whereas the HBT 20 in Example 3 includes two emitter electrodes 31E (see FIG. 5) and two emitter mesas 28 (see FIG. 6). The two emitter electrodes 31E are each longer in one direction than in the other directions and are discretely located away from each other in the width direction thereof. The two emitter mesas 28 include the respective ballast resistance layers 25. That is, the two ballast resistance layers 25 are discretely located away from each other when the emitter layer 21E is viewed in plan.

The base electrode 31B includes one finger portion 31BA, which is located between two emitter electrodes 31E when viewed in plan. That is, the finger portion 31BA of the base electrode 31B is disposed between the two ballast resistance layers 25. The contact portion 31BB is longer in the width direction of the emitter electrodes 31E than in the other directions and is connected to an end of the finger portion 31BA. The base electrode 31B is thus T-shaped when viewed in plan.

The emitter line 35E in the first layer extends over the emitter electrodes 31E and across the finger portion 31BA of the base electrode 31B located between the emitter electrodes 31E. The emitter line 35E is electrically connected to the two emitter electrodes 31E.

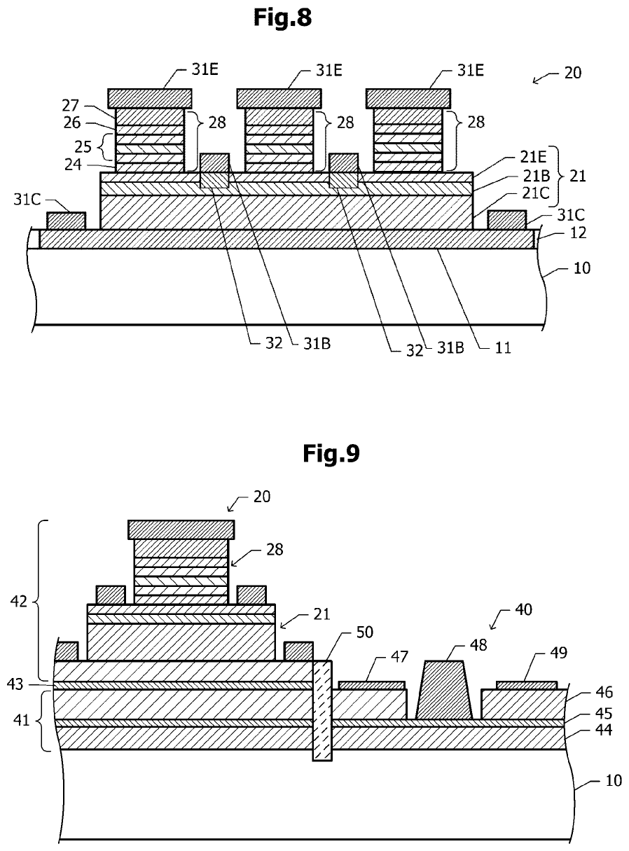

The following describes an HBT in a variation of Example 3 with reference to FIGS. 7 and 8. FIG. 7 is a plan view of the HBT 20 in the variation of Example 3, and FIG. 8 is a sectional view of the HBT 20 taken along dash-dot line 8-8 in FIG. 7.

The HBT 20 in the variation of Example 3 includes three emitter electrodes 31E (see FIG. 7) and three emitter mesas 28 (see FIG. 8). The three emitter mesas 28 include the respective ballast resistance layers 25. That is, the three ballast resistance layers 25 are discretely located away from each other when the emitter layer 21E is viewed in plan. The three emitter electrodes 31E are each longer in one direction than in the other directions and are arranged side by side in the width direction thereof. As in Example 1, the base electrode 31B is U-shaped and includes two finger portions 31BA, each of which is located between two adjacent emitter electrodes 31E. That is, each of the two finger portions 31BA of the base electrode 31B is disposed between two of the three ballast resistance layers 25 that are adjacent to each other.

Alternatively, four or more emitter mesas 28 may be provided. This means that four or more ballast resistance layers 25 may be provided and discretely located away from each other. In this case as well, each of the finger portions 31BA of the base electrode 31B is preferably disposed between two of the ballast resistance layers 25 that are adjacent to each other.

The following describes advantageous effects of Example 3 and its variation. Example 3 and its variation in which more than one emitter electrodes 31E and more than one emitter mesas 28 are provided may adopt the structure of the ballast resistance layer 25 described above in relation to Example 1 so that the emitter mesas 28 can be reduced in thickness. This increases the processing accuracy for the emitter mesa 28. This effect of increasing the processing accuracy for the emitter mesa 28 is more noticeable in the HBT 20 Example 3 and its variation that involve the process of forming more than one emitter mesa 28 on one collector mesa 21.

### Example 4

The following describes a semiconductor device in Example 4 with reference to FIG. 9. The features of the HBT that are common to Example 4 and Example 1 described above with reference to FIGS. 1 to 3 will not be further elaborated on here.

FIG. 9 is a sectional view of the semiconductor device in Example 4. Example 4 makes combined use of the HBT 20 and a high-electron-mobility transistor (HEMT) 40, both of which are disposed on the substrate 10. Such a semiconductor device is sometimes called BiHEMT. The substrate 10 that is a semi-insulating substrate is overlaid with a multilayer structure including an HEMT structure layer 41, a separation layer 43 on the HEMT structure layer 41, and an HBT structure layer 42 on the separation layer 43. The HEMT 40 is provided in a region where the separation layer 43 and the HBT structure layer 42 are partially removed. The region for the placement of the HBT 20 and the region for the placement of the HEMT 40 are separated by an insulating part 50, which extends through the HEMT structure layer 41 in the thickness direction.

The HEMT structure layer 41 includes an operation layer 44, a Schottky layer 45 on the operation layer 44, and a contact layer 46 on the Schottky layer 45. The operation layer 44 includes, for example, a carrier supply layer, a spacer layer, and a channel layer. A gate electrode 48 in Schottky contact with the Schottky layer 45 is provided in a region where the contact layer 46 is partially removed to expose the Schottky layer 45. The gate electrode 48 is sandwiched between a source electrode 47 and a drain electrode 49, which are disposed on the contact layer 46.

The HBT structure layer 42 includes layers constituting the HBT in Example 1 (see FIG. 2), with the sub-collector layer 11 at the bottom and the contact layer 27 at the top. The layers included in the HBT structure layer 42 constitute the HBT 20.

The following describes advantageous effects of Example 4. As with Example 1, Example 4 yields an improvement in the processing accuracy for the emitter mesa 28 and the collector mesa 21. This enables reductions in product-to-product size variation. The greater processing accuracy can also lead to enhanced production yield and a reduction in cost.

### Example 5

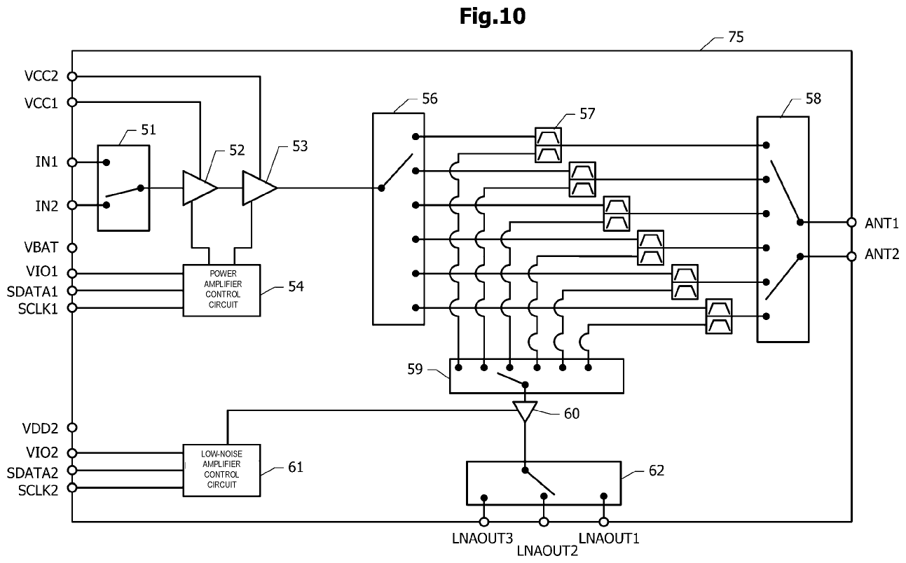

The following describes a communication module in Example 5 with reference to FIGS. 10 to 13. The HBT 20 in Example 1, Example 2, Example 3, or the variation of Example 3 is incorporated in the communication module in Example 5.

FIG. 10 is a block diagram of a communication module 75 in Example 5. The communication module 75 includes an input switch 51, a driver-stage amplifier 52, a power-stage amplifier 53, a band selection switch 56 for transmission, duplexers 57, an antenna switch 58, a band selection switch 59 for reception, a low-noise amplifier 60, a power amplifier control circuit 54, a low-noise amplifier control circuit 61, and an output terminal selection switch 62 for reception. The communication module 75 is capable of transmission and reception in the frequency division duplex (FDD) mode. Impedance matching circuits may be included as necessary but are not illustrated in FIG. 10.

The input switch 51 includes two input contacts that are connected to radio-frequency signal input terminals IN1 and IN2, respectively. Radio-frequency signals are input through the radio-frequency signal input terminals IN1 and IN2. One of the two input contacts is selected, and a radio-frequency signal input to the selected contact of the input switch 51 is then input to the driver-stage amplifier 52.

The radio-frequency signal is amplified by the driver-stage amplifier 52 and is then input to the power-stage amplifier 53. The radio-frequency signal is amplified by the power-stage amplifier 53 and is then input to an input contact of the band selection switch 56. One output contact is selected from among output contacts of the band selection switch 56, and the radio-frequency signal amplified by the power-stage amplifier 53 is then output through the selected contact.

The output contacts of the band selection switch 56 are connected to transmission input ports of the duplexers 57, which are provided for the respective bands. The radio-frequency signal is input to the duplexer 57 connected to the selected output contact of the band selection switch 56. The band selection switch 56 is capable making a selection from among the duplexer 57 provided for the respective bands.

The antenna switch 58 includes more than one circuit contact and two antenna contacts. Each of the circuit contacts of the antenna switch 58 is connected to an input-output common port of the corresponding one of the duplexers 57. The two antenna contacts of the antenna switch 58 are connected to an antenna terminal ANT1 and an antenna terminal ANT2, respectively. The antenna terminals ANT1 and ANT2 are connected to the respective antennas.

The antenna switch 58 connects the two antenna contacts to the respective selected circuit contacts. For single-band communication, the antenna switch 58 connects one of the circuit contacts to one of the antenna contacts. The radio-frequency signal amplified by the power-stage amplifier 53 and transmitted through the duplexer 57 provided for the band concerned is transmitted through the antenna connected to the selected antenna contact.

The band selection switch 59 for reception includes six input contacts. The six input contacts of the band selection switch 59 are connected to the respective reception output ports of the duplexers 57. The band selection switch 59 includes one output contact, which is connected to the low-noise amplifier 60. A reception signal transmitted through the duplexer 57 connected to the selected input contact of the band selection switch 59 is input to the low-noise amplifier 60.

The output terminal selection switch 62 includes a circuit contact connected to an output port of the low-noise amplifier 60. The output terminal selection switch 62 includes three terminal contacts connected to reception signal output terminals LNAOUT1, LNAOUT2, and LNAOUT3, respectively. The reception signal is amplified by the low-noise amplifier 60 and is then output through the reception signal output terminal selected by the output terminal selection switch 62.

The power supply voltage is applied to the driver-stage amplifier 52 and the power-stage amplifier 53 through a power supply terminal VCC1 and a power supply terminal VCC2, respectively. The power amplifier control circuit 54 is connected to a power supply terminal VIO1, a control signal terminal SDATA1, and a clock terminal SCLK1. The power amplifier control circuit 54 controls the driver-stage amplifier 52 and the power-stage amplifier 53 in accordance with a digital control signal input to the control signal terminal SDATA1. More specifically, an internal analog circuit of the power amplifier control circuit 54 provides desired bias to the driver-stage amplifier 52 and the power-stage amplifier 53 in accordance with the digital control signal input to the control signal terminal SDATA1.

The low-noise amplifier control circuit 61 is connected to a power supply terminal VIO2, a control signal terminal SDATA2, and a clock terminal SCLK2. The low-noise amplifier control circuit 61 controls the low-noise amplifier 60 in accordance with a digital control signal input to the control signal terminal SDATA2. More specifically, an internal analog circuit of the low-noise amplifier control circuit 61 provides desired bias to the low-noise amplifier 60 in accordance with the digital control signal input to the control signal terminal SDATA2.

In addition to these terminals, a power supply terminal VBAT and a drain voltage terminal VDD2 are provided to the communication module 75. Electric power provided through the power supply terminal VBAT is supplied to a bias circuit of the driver-stage amplifier 52, a bias circuit of the power-stage amplifier 53, and a power amplifier control circuit 54. Power supply voltage provided through the drain voltage terminal VDD2 is applied to, for example, the low-noise amplifier control circuit 61.

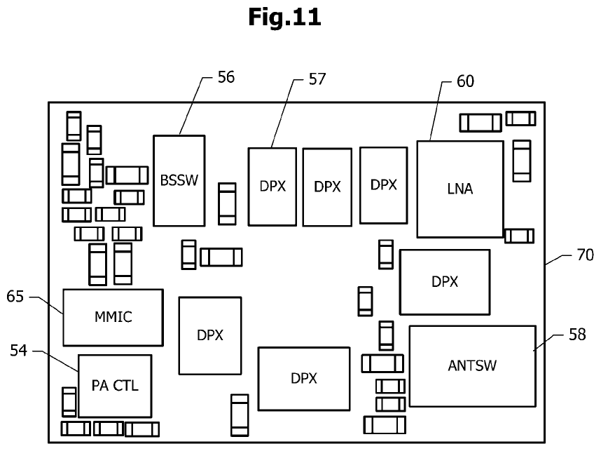

FIG. 11 is a plan view of a module substrate 70, illustrating an example layout of various circuit elements mounted on the module substrate 70. A monolithic microwave integrated circuit (MMIC) 65, the power amplifier control circuit 54, the band selection switch 56, the duplexers 57, the low-noise amplifier 60, the antenna switch 58, and other passive elements are mounted on the module substrate 70. The MMIC 65 includes the driver-stage amplifier 52 (see FIG. 10) and the power-stage amplifier 53 (see FIG. 10). The circuit components are mounted on the module substrate 70 through, for example, the process of solder ball mounting, Cu pillar bump (CPB) mounting, or face-up mounting. The face-up mounting involves the use of bonding wires that form connections between elements and pads on the module substrate 70.

The module substrate 70 is a multilayer substrate, such as a multilayer printed circuit board (PCB) or a multilayer ceramic substrate. The structure illustrated in FIG. 11 is obtained by single-sided mounting. Alternatively, high-density packaging through the use of a double-sided mounting board or an IC embedded in the substrate may be adopted. The adoption of high-density packaging enables a reduction in the size of the communication module 75 (see FIG. 10).

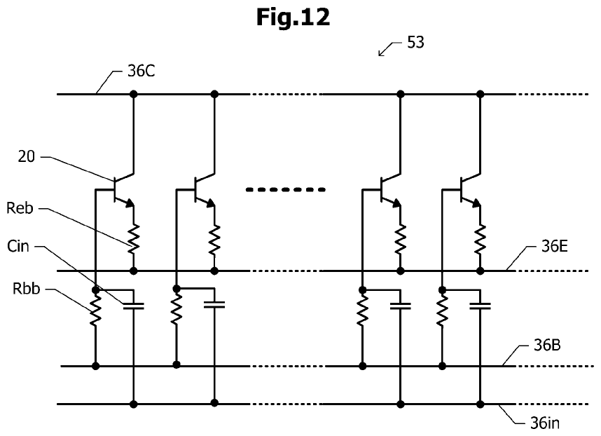

FIG. 12 is an equivalent circuit diagram of part of the power-stage amplifier 53. The power-stage amplifier 53 includes HBTs 20 connected in parallel. Each of the HBTs 20 is the HBT 20 in Example 1 (see FIGS. 1 and 2), the HBT in Example 2 (see FIG. 4), the HBT 20 in Example 3 (see FIGS. 5 and 6), or the HBT 20 in the variation of Example 3 (see FIGS. 7 and 8). Collectors of the HBTs 20 are connected to a collector common line 36C. Bases of the HBTs 20 are connected to a base bias line 36B with base ballast resistors Rbb therebetween and are connected to a radio-frequency signal input line 36in with input capacitors Cin therebetween. Emitters of the HBTs 20 are connected to an emitter common line 36E with emitter ballast resistors Reb therebetween. Each of the emitter ballast resistors Reb is the ballast resistance layer 25 (see FIGS. 2, 4, 6, and 8) included in the emitter mesa 28.

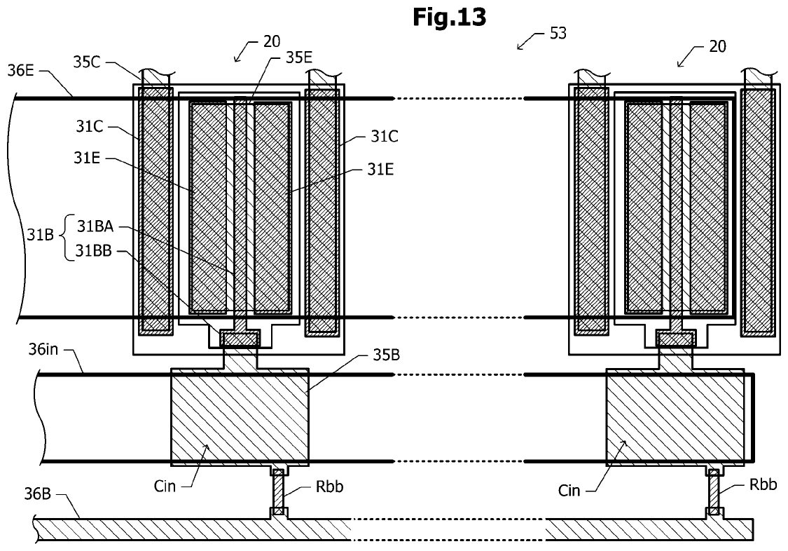

FIG. 13 is a plan view of part of the power-stage amplifier 53. As with the HBT 20 (see FIG. 5) in Example 2, the HBTs 20 illustrated in FIG. 13 each include two emitter electrodes 31E, one T-shaped base electrode 31B, and two collector electrodes 31C. The HBTs 20 are arranged side by side in the width direction of the emitter electrodes 31E. The emitter common line 36E in a second layer lies over the emitter line 35E in the first layer of each of the HBTs 20 and extends in the direction in which the HBTs 20 are arranged side by aside. The emitter common line 36E connects emitters of the HBTs 20 to each other. The collector lines 35C in the first layer is connected to the respective collector electrodes 31C.

Each of the base lines 35B in the first layer overlaps the contact portion 31BB of the base electrode 31B of the corresponding one of the HBTs 20 and is extended beyond the overlap. The base lines 35B each have a part wider than the other part. The radio-frequency signal input line 36in in the second layer overlaps the wider part of each of the base lines 35B. The overlap between each of the base lines 35B in the first layer and the radio-frequency signal input line 36in in the second layer serves as the input capacitor Cin. The base lines 35B are connected to the base bias line 36B with the base ballast resistors Rbb therebetween.

Referring to FIG. 13, the emitter electrodes 31E, the base electrodes 31B, and the collector electrodes 31C are more densely hatched, whereas the lines in the first layer or, more specifically, the emitter lines 35E, the collector lines 35C, the base lines 35B, and the base bias line 36B are less densely hatched.

The following describes advantageous effects of Example 5. The HBTs 20 described above in relation to, for example, Example 1 are included in the power-stage amplifier 53 of the communication module 75 in Example 5. This eliminates or reduces the possibility that the HBTs 20 will exhibit thermal runaway. The communication module 75 is thus capable of providing higher output power. This increases the processing accuracy in the production of the MMIC 65.

The base ballast resistors Rbb connected to the HBTs 20 eliminates or reduces the unevenness in the emitter current flowing through the HBTs 20. Accordingly, the breakdown withstand voltage of the module as a whole can be increased.

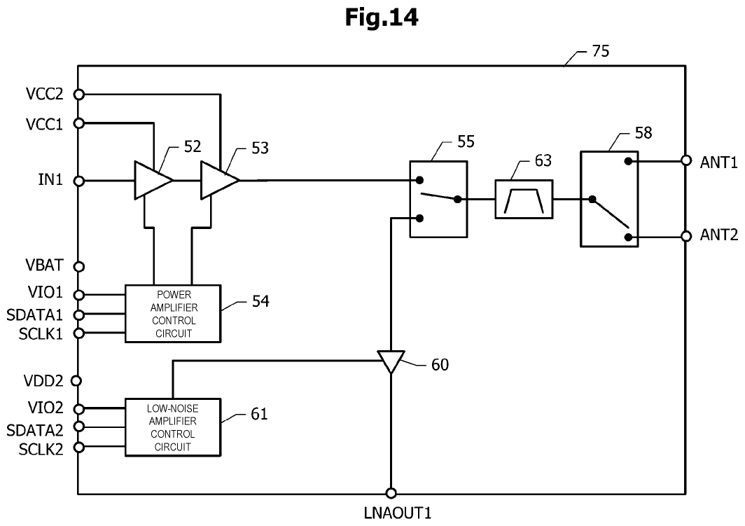

The following describes a communication module in a variation of Example 5 with reference to FIG. 14. FIG. 14 is a block diagram of the communication module 75 in the variation of Example 5. The features of the communication module 75 that are common to Example 5 and the variation of Example 4 will not be further elaborated on here. The communication module 75 in this variation does not include the input switch 51, the band selection switches 56 and 59, and the output terminal selection switch 62 that are illustrated in FIG. 10.

The communication module 75 in Example 5 (see FIG. 10) is designed for communication in the FDD mode. This involves the use of the duplexers 57 (see FIG. 10) serving as frequency selection elements. Unlike the communication module 75 in Example 5, the communication module 75 in this variation is designed for communication in time division duplex (TDD) mode. This involves the use of a filter 63, which serves as a frequency selection element.

An output port of the power-stage amplifier 53 is connected to a transmission contact of a transmission/reception change-over switch 55. An input port of the low-noise amplifier 60 is connected to a reception contact of the transmission/reception change-over switch 55. A common contact of the transmission/reception change-over switch 55 is connected to a circuit contact of the antenna switch 58 with the filter 63 being located the common contact and the circuit contact. Two antenna contacts of the antenna switch 58 are connected to the antenna terminal ANT1 and the antenna terminal ANT2, respectively.

As in the variation described above with reference to FIG. 14, the HBT 20 in, for example, Example 1 may be incorporated in the communication module 75 designed for communication in the TDD mode.

Those described above are merely examples. Needless to say, partial replacements or combinations of features in different examples are possible. Different examples may produce effects relevant to similar features; however, in some examples, no mention has been made again of such effects. Furthermore, the present disclosure is not intended to be limited to the above-described examples. For example, it will be obvious to those skilled in the art that various changes, improvements, combinations, and the like may be made.

What is claimed is:

1. A heterojunction bipolar transistor comprising:
a collector layer including an n-type compound semiconductor material;
a base layer on the collector layer, the base layer including a p-type compound semiconductor material;
an emitter layer on the base layer, the emitter layer including an n-type compound semiconductor material having a band gap larger than a band gap of the base layer; and
at least one ballast resistance layer on the emitter layer, the ballast resistance layer including an intrinsic or p-type compound semiconductor material.

2. The heterojunction bipolar transistor according to claim 1, wherein
the ballast resistance layer and the collector layer include a same compound semiconductor.

3. The heterojunction bipolar transistor according to claim 1, wherein
the ballast resistance layer includes two n-type layers including an n-type compound semiconductor material and a p-type layer between the two n-type layers and including a p-type compound semiconductor material.

4. The heterojunction bipolar transistor according to claim 3, wherein
a donor concentration in each of the two n-type layers and an acceptor concentration in the p-type layer are each less than or equal to 1×10¹⁶ cm⁻³.

5. The heterojunction bipolar transistor according to claim 1, wherein
the collector layer and the base layer each include a GaAs compound semiconductor material.

6. The heterojunction bipolar transistor according to claim 1, further comprising:
a base electrode electrically connected to the base layer, wherein
the heterojunction bipolar transistor comprises a plurality of the ballast resistance layers,
the plurality of heterojunction bipolar transistors are discretely located away from each other when the emitter layer is viewed in plan, and
part of the base electrode is between the plurality of ballast resistance layers.

7. A semiconductor device comprising:
a substrate;
the heterojunction bipolar transistor according to claim 1, the heterojunction bipolar transistor being on the substrate; and
a high-electron-mobility transistor on the substrate.

8. A communication module comprising:
the heterojunction bipolar transistor according to claim 1;
an antenna terminal connected to an antenna; and
a frequency selection element connected between the heterojunction bipolar transistor and the antenna terminal.

9. The heterojunction bipolar transistor according to claim 2, wherein
the ballast resistance layer includes two n-type layers including an n-type compound semiconductor material and a p-type layer between the two n-type layers and including a p-type compound semiconductor material.

10. The heterojunction bipolar transistor according to claim 2, wherein
the collector layer and the base layer each include a GaAs compound semiconductor material.

11. The heterojunction bipolar transistor according to claim 3, wherein
the collector layer and the base layer each include a GaAs compound semiconductor material.

12. The heterojunction bipolar transistor according to claim 4, wherein
the collector layer and the base layer each include a GaAs compound semiconductor material.

13. The heterojunction bipolar transistor according to claim 2, further comprising:
a base electrode electrically connected to the base layer, wherein
the heterojunction bipolar transistor comprises a plurality of the ballast resistance layers,
the plurality of heterojunction bipolar transistors are discretely located away from each other when the emitter layer is viewed in plan, and
part of the base electrode is between the plurality of ballast resistance layers.

14. The heterojunction bipolar transistor according to claim 3, further comprising:
a base electrode electrically connected to the base layer, wherein
the heterojunction bipolar transistor comprises a plurality of the ballast resistance layers,
the plurality of heterojunction bipolar transistors are discretely located away from each other when the emitter layer is viewed in plan, and
part of the base electrode is between the plurality of ballast resistance layers.

15. The heterojunction bipolar transistor according to claim 4, further comprising:
a base electrode electrically connected to the base layer, wherein
the heterojunction bipolar transistor comprises a plurality of the ballast resistance layers,
the plurality of heterojunction bipolar transistors are discretely located away from each other when the emitter layer is viewed in plan, and
part of the base electrode is between the plurality of ballast resistance layers.

16. A semiconductor device comprising:
a substrate;
the heterojunction bipolar transistor according to claim 2, the heterojunction bipolar transistor being on the substrate; and
a high-electron-mobility transistor on the substrate.

17. A semiconductor device comprising:
a substrate;
the heterojunction bipolar transistor according to claim 3, the heterojunction bipolar transistor being on the substrate; and
a high-electron-mobility transistor on the substrate.

18. A semiconductor device comprising:
a substrate;
the heterojunction bipolar transistor according to claim 4, the heterojunction bipolar transistor being on the substrate; and
a high-electron-mobility transistor on the substrate.

19. A communication module comprising:
the heterojunction bipolar transistor according to claim 2;
an antenna terminal connected to an antenna; and
a frequency selection element connected between the heterojunction bipolar transistor and the antenna terminal.

20. A communication module comprising:
the heterojunction bipolar transistor according to claim 3;
an antenna terminal connected to an antenna; and
a frequency selection element connected between the heterojunction bipolar transistor and the antenna terminal.
